(19) United States
(12) Patent Application Publication
(10) Pub. No.: US 2006/0152902 A1
(43) Pub. Date: Jul. 13, 2006

(54) Radiation body and a device cooling a heating element using the radiation body

(75) Inventor: Noseong Park, Seongnam City (KR)

Correspondence Address: ROTHWELL, FIGG, ERNST & MANBECK, P.C., 1425 K STREET, N.W., SUITE 800, WASHINGTON, DC, 20005, US

(73) Assignee: O-FAN CO., LTD, Seongnam City (KR)

(21) Appl. No.: 10/546,603

(22) PCT Filed: Apr. 2, 2004
(86) PCT No.: PCT/KR04/00769

§ 371 Date: Aug. 23, 2005

(30) Foreign Application Priority Data
Apr. 3, 2003 (KR) 20-2003-0010111
Feb. 20, 2004 (KR) 10-2004-0011237
Apr. 1, 2004 (KR) 10-2004-0022614

(51) Int. Cl. H05K 7/20

(52) U.S. Cl. 361/697; 361/718

(57) ABSTRACT

The present invention relates to a radiation element and a device for cooling a heating element using the radiation element, which can reduce noise, increase discharge air volume, and improve cooling efficiency. The radiation element includes: a mounting part on which a heating element is mounted; and air discharging means mounted on the mounting part having a space for receiving a cooling fan and a number of air discharge slits for discharging air generated from the cooling fan in the horizontal direction along the circumference of the cooling fan. The device for cooling a heating element includes: a sirocco fan having a number of blades mounted in the circumferential direction thereof; a radiation element having a space for receiving the sirocco fan and air discharging means, which has a number of air discharge slits formed by a number of air discharge guide members mounted at regular intervals in the same direction as the blades along the circumference of the sirocco fan; a motor for rotating the sirocco fan contained in the radiation element; and mounting means for mounting the motor and a heating element.

### TECHNICAL FIELD

The present invention relates to a radiation element and a device for cooling a heating element using the radiation element, and more particularly, to a radiation element and a device for cooling a heating element using the radiation element, which can reduce noise, increase discharge air volume, and improve cooling efficiency.

### BACKGROUND ART

In general, an electronic apparatus, such as a personal computer, a computer for server, an unmanned sensing system adopting a picture compression technology, a mobile communication relay system, and so on, has a chip module capable of processing a great deal of data.

Such chip module generates a lot of heat during processing data, and so, causes errors, which may severely bad influence on the operation of the electronic apparatus when the generated heat is increased more than a predetermined temperature.

To prevent the errors of the chip module, a cooling device for forcible cooling of the heat is mounted on the chip module (hereinafter, called a “heating element”)

The cooling device is applied not only to the chip module used in the electronic apparatus but also to all heat generating means for generating heat.

The cooling device is divided into a heat sink type and a heat pipe type.

The heat sink type cooling device includes a sink pad for absorbing the generated heat, and a radiation fin for cooling the heat transferred from the sink pad.

The heat pipe type cooling device includes a heat absorbing part for absorbing the heat of the heating element, and a radiation part for emitting the absorbed heat to the outside.

Recently, the heat sink type cooling device has been greatly developed and marketed due to its simple productivity and low production cost. FIGS. 1 and 2 show the heat sink type cooling device.

As shown in FIGS. 1 and 2, a cooling device 2 includes a heat sink 3 fixed on a heating element 1, and an axial fan 6 fixed on the upper portion of the heat sink 3 by means of fixing means, such as a bolt.

The heat sink 3 has a number of radiation fins 5 integrally formed on the upper portion of a plate 4 in multiple rows.

When the axial fan 6 is driven, heat transferred to the radiation fins 5 of the heat sink 3 is cooled by cooling wind that is generated from the axial fan 6 and passing through the radiation fins 5.

The heat generated from the heating element 1 is cooled by the wind generated from the axial fan 6 while continuously moving to the radiation fins 5 after passing the plate 4 of the heat sink 3.

However, the conventional cooling device 2 having the above structure has several problems as follows.

First, the conventional cooling device 2 increases noise as resistance is increased due to vortex and separation occurring while the wind passes the radiation fin 5 when the axial fan 6 is rotated at a high speed to increase air flow of the wind.

Second, lots of wind must be blown to increase cooling efficiency of the heating element 1, but in this case, the conventional cooling device consumes lots of electric power due to the high-speed rotation of the axial fan 6.

Third, in the structure of the radiation fins 5 of the conventional cooling device, the cooling efficiency of the heating element 1 is decreased because the wind generated from the axial fan 6 cannot be discharged out smoothly and stagnated in spaces between the radiation fins 5.

### DISCLOSURE OF INVENTION

Accordingly, the present invention has been made in view of the above problems, and it is an object of the present invention to provide a radiation element and a device for cooling a heating element using the radiation element, which can reduce noise, increase discharge air volume, and improve cooling efficiency.

To achieve the above object, in an aspect, the present invention provides a radiation element comprising: a mounting part on which a heating element is mounted; and air discharging means mounted on the mounting part having a space for receiving a cooling fan and a number of air discharge slits for discharging air generated from the cooling fan in the horizontal direction along the circumference of the cooling fan.

In another aspect, the present invention provides a device for cooling a heating element comprising: a sirocco fan having a number of blades mounted in the circumferential direction thereof; a radiation element having a space for receiving the sirocco fan and air discharging means, which has a number of air discharge slit formed by a number of air discharge guide members mounted at regular intervals in the same direction as the blades along the circumference of the sirocco fan; a motor for rotating the sirocco fan contained in the radiation element; and mounting means for mounting the motor and a heating element.

In a further aspect, the present invention provides a device for cooling heating element comprising: a sirocco fan having a number of blades mounted in the circumferential direction thereof; a mounting part on which a heating element is attached; a radiation element mounted on the mounting part and having a space for receiving the sirocco fan and air discharging means, which has a number of air discharge slits for discharging air in the perpendicular direction to the blades along the circumference of the sirocco fan; a motor for rotating the sirocco fan contained in the radiation element; and mounting means for mounting the motor and a heating element.

### BRIEF DESCRIPTION OF DRAWINGS

Further objects and advantages of the invention can be more fully understood from the following detailed description taken in conjunction with the accompanying drawings in which:

FIG. 1 is a perspective view showing the outward appearance of a conventional cooling device;

FIG. 2 is a sectional view of FIG. 1;

FIG. 3 is an exploded perspective view of a first preferred embodiment of the present invention;

FIG. 4 is a plan view of FIG. 3, in a state where a sirocco fan is embedded;

FIG. 5 is a vertically sectional view of FIG. 3;

FIG. 6 is an exploded perspective view, in part, of a second preferred embodiment of the present invention;

FIG. 7 is an exploded perspective view, in part, of a third preferred embodiment of the present invention;

FIG. 8 is a perspective view showing an assembled state of FIGS. 6 and 7;

FIG. 9 is an exploded perspective view, in part, of a fourth preferred embodiment of the present invention;

FIG. 10 is an exploded perspective view, in part, of a fifth preferred embodiment of the present invention;

FIG. 11 is a perspective view showing an assembled state of FIGS. 9 and 10;

FIG. 12 is a perspective view of a sixth preferred embodiment of the present invention; and

FIG. 13 is a sectional view of FIG. 12.

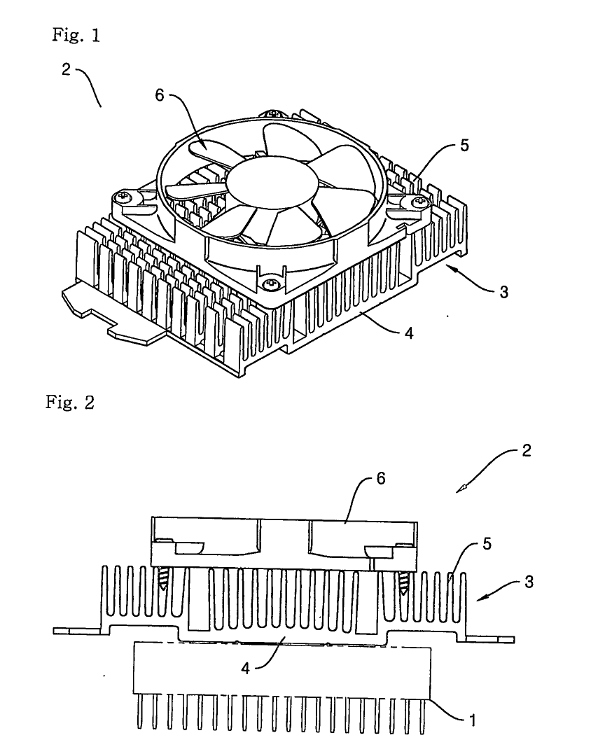

### EXPLANATION OF REFERENCE NUMERALS OF ESSENTIAL PARTS IN DRAWINGS

100: mounting part

200,300,400: air discharging means

210: air discharge slit

211: air discharge guide member

500: concentratively discharging means

311: air discharge guide member

110: mounting member

310: unit member

320: spacer

330: coupling means

410: first unit member

411: air discharge guide member

411a: receiving hole

420: second unit member

421: air discharge guide member

421a: receiving hole

430: coupling means

510: fitting part

520: connecting part

600: motor mounting means

610: motor mounting part

620: bridge part

700: sirocco fan

710: blade

800: heating element

### BEST MODE FOR CARRYING OUT THE INVENTION

The present invention will now be described in detail in connection with preferred embodiments with reference to the accompanying drawings.

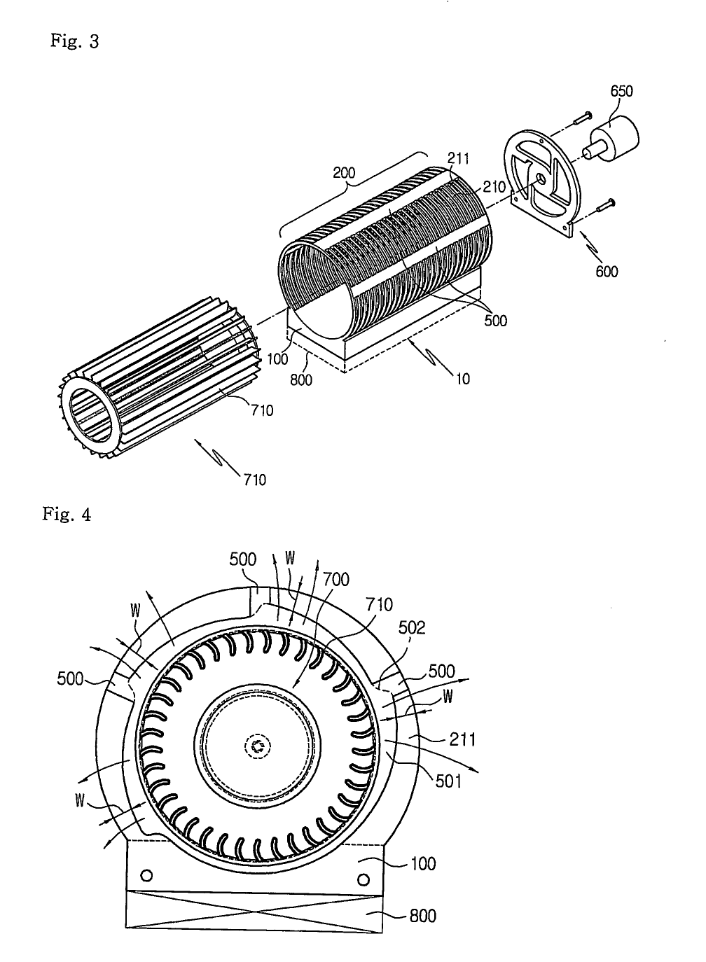

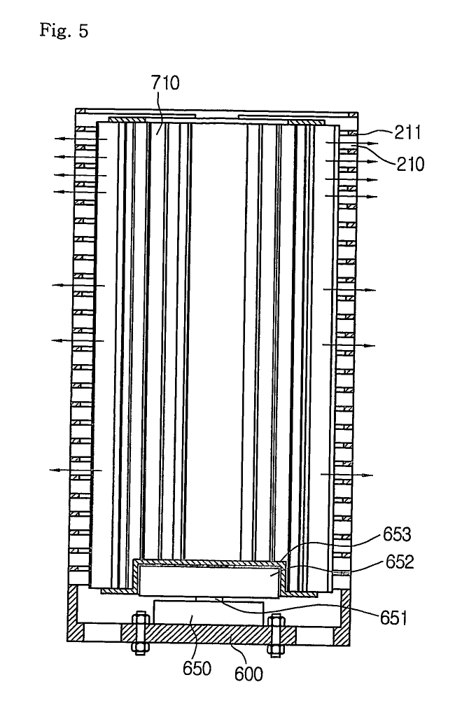

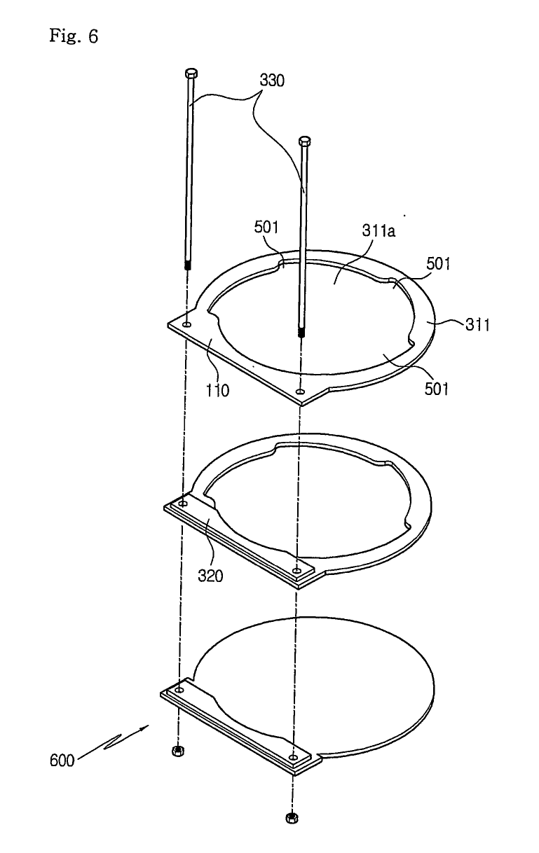

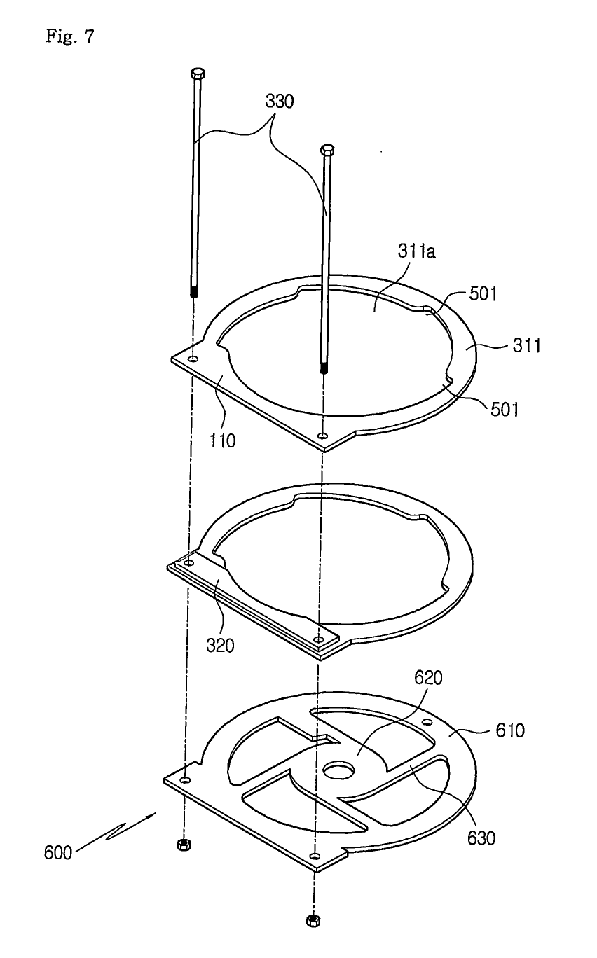

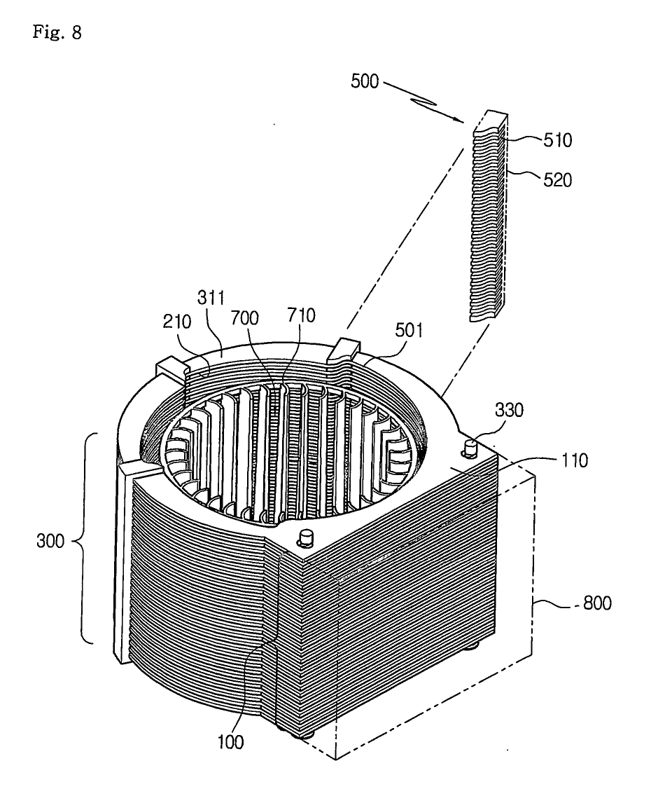

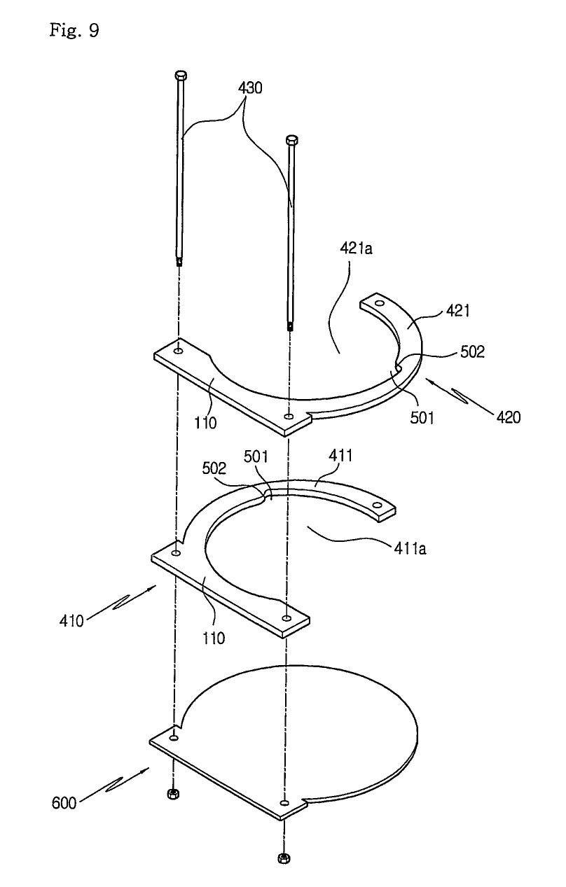

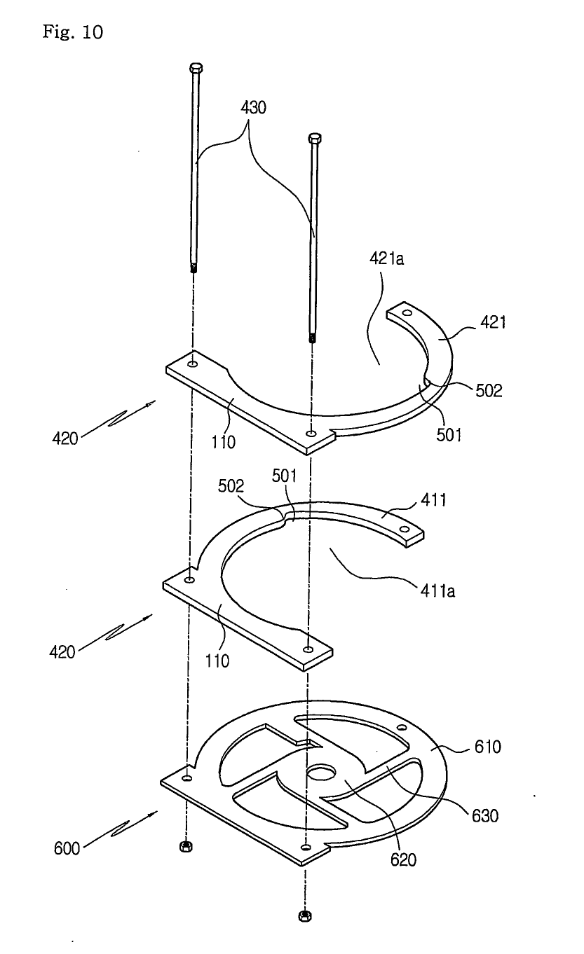

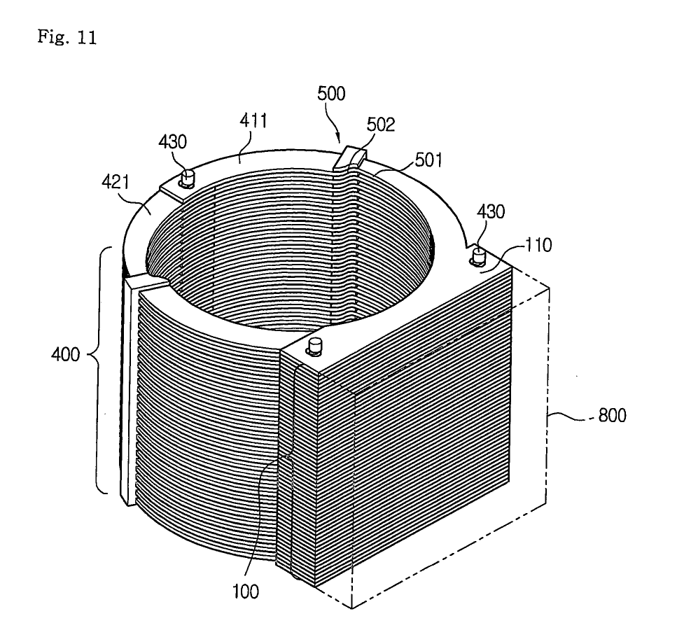

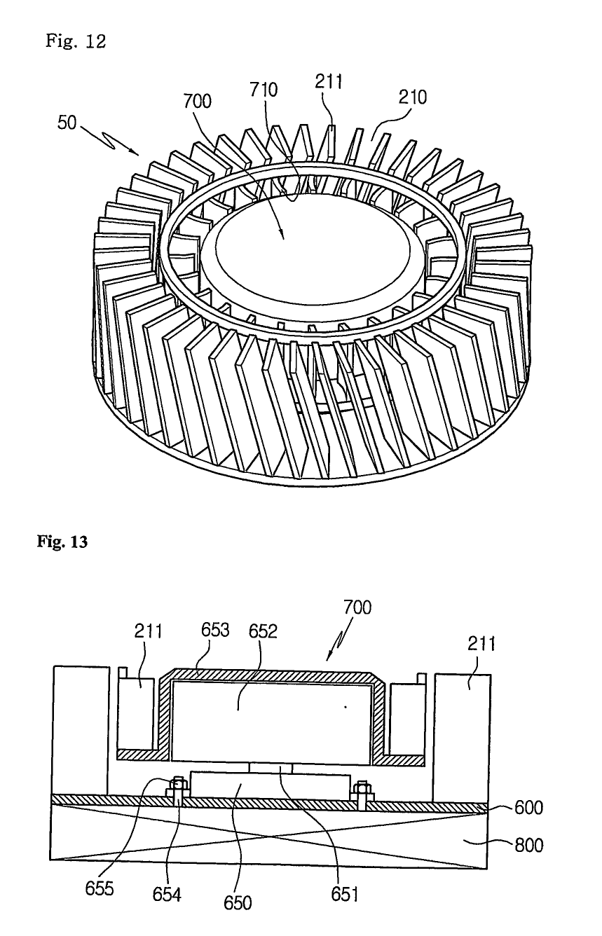

FIG. 3 is an exploded perspective view of a first preferred embodiment of the present invention, FIG. 4 is a plan view of FIG. 3, in a state where a sirocco fan is embedded, FIG. 5 is a vertically sectional view of FIG. 3, FIG. 6 is an exploded perspective view, in part, of a second preferred embodiment of the present invention, FIG. 7 is an exploded perspective view, in part, of a third preferred embodiment of the present invention, FIG. 8 is a perspective view showing an assembled state of FIGS. 6 and 7, FIG. 9 is an exploded perspective view, in part, of a fourth preferred embodiment of the present invention, FIG. 10 is an exploded perspective view, in part, of a fifth preferred embodiment of the present invention, FIG. 11 is a perspective view showing an assembled state of FIGS. 9 and 10, FIG. 12 is a perspective view of a sixth preferred embodiment of the present invention, and FIG. 13 is a sectional view of FIG. 12.

A radiation element according to the present invention includes: a mounting part 100 for attaching a heating element 800; and air discharging means 200, 300 or 400 mounted on the mounting part 100 and having a space for receiving a cooling fan 700, and a number of air discharge slits 210 for discharging air generated from the cooling fan 700 in a perpendicular direction along the circumference of the cooling fan.

Here, as the cooling fan 700, a sirocco fan having a number of blades 710 is used.

The air discharging means 200 has at least one or more concentratively discharging means 500 mounted in the air discharge slit 210 for branching and discharging the air generated from the cooling fan 700 and for concentratively discharging the air to a specific part by blocking a predetermined section of the air discharge slit 210.

The concentratively discharging means 500 are mounted in a straight line.

Therefore, the wind generated from the sirocco fan 700 can be concentratively discharged at an area of the concentratively discharging means 500.

As shown in FIGS. 4 to 6, the air discharging means 200 according to the first preferred embodiment of the present invention includes a number of air discharge guide members 211 separated from each other and piled up on another to form the air discharge slit 210. The air discharge guide members 211 of the air discharging means 200 and the mounting part 100 are integrated with each other into one.

Meanwhile, as shown in FIGS. 7 to 9, the air discharging means 300 includes unit members 310, spacers 320 and coupling means 330.

Each of the unit members 310, which are piled up in multiple layers, includes a ring type air discharge guide member 311 having a hole 311a for receiving the cooling fan 700, and a mounting member 110 protruding from a side of the air discharge guide member 311 for mounting of the heating element 800.

The spacers 320 are arranged between the mounting members 110 of the unit members 310, and form the air discharge slit 210 between the air discharge guide members 311.

The coupling means 330 connects the spacer 320 and the mounting member 110 with each other.

The mounting part 100 is formed by a number of the mounting members 110 piled up on another, and the air discharging means 300 is formed by the air discharge guide member 311.

Next, as shown in FIG. 9 and 11, the air discharging means 400 according to the third preferred embodiment of the present invention includes a first unit member 410, a second unit member 420, and coupling means 430.

The first unit member 410 includes: a first mounting member 110 on which the heating element 800 is attached; and an air discharge guide member 411 protruding integrally from a side of the mounting member 110 and having a receiving hole 411a for receiving half of the cooling fan 700.

The second unit member 420 includes: a second mounting member 110, which is piled up on the upper surface of the first mounting member 110 of the first unit member 410, and, on which the heating element 800 is attached; and an air discharge guide member 421 protruding integrally from a side of the second mounting member 110 opposed to the air discharge guide member 411 of the first unit member 410 and having a receiving hole 421a for receiving the other half of the cooling fan 700, wherein an end portion of the air discharge guide member 421 is put on the upper surface of the air discharge guide member 411 of the first unit member 410 to form an air discharge slit 210.

The coupling means 430 connects and fixes the ends of the air discharge guide members 411 and 421 and the first and second mounting members 110 with each other when a number of the first and second unit members 410 and 420 are piled up in order.

The mounting part 100 is formed by a number of the mounting members 110 piled up on another, and the air discharging means 400 is formed by the air discharge guide members 411 and 421.

In the above structure, if only one concentratively discharging means 500 is mounted, the concentratively discharging means 500 has a number of air guide holes 501 formed in such a manner that the air discharge guide member 211, 311, 411 or 421 is gradually narrowed from the mounting part 100 to the front end of the concentratively discharging means 500 and gradually narrowed from the rear end of the concentratively discharging means 500 to the mounting part 100.

In more detail, an interval between the inner surface of the air discharge guide member 211, 311, 411 or 421 and the outer surface of the blade 710 of the sirocco fan 700 is gradually increased from the mounting part 100 to the front end of the concentratively discharging means 500.

Meanwhile, if a number of the concentratively discharging means 500 are mounted, the concentratively discharging means 500 has a number of air guide holes 501 formed in such a manner that the air discharge guide member 211, 311, 411 or 421 is gradually narrowed from the mounting part 100 to the front end of the concentratively discharging means 500, gradually narrowed from the rear end of the concentratively discharging means 500 to the front end of another concentratively discharging means 500, and gradually narrowed from the rear end of the latter concentratively discharging means 500 to the mounting part 100.

In more detail, the interval between the inner surface of the air discharge guide member 211, 311, 411 or 421 and the outer surface of the blade 710 of the sirocco fan 700 is gradually increased from the mounting part 100 to the front end of the concentratively discharging means 500, gradually increased from the rear end of the concentratively discharging means 500 to the front end of the latter concentratively discharging means 500, and gradually increased from rear end of the latter concentratively discharging means 500 to the mounting part 100.

Here, noise reduction surfaces 502 for reducing noise generated when the concentratively discharging means 500 is collided with the ventilated air are formed on the inner surface of the concentratively discharging means 500 adjacent to the rear end of the air guide hole 501, on the inner surface of the air guide member 211, 311, 411 or 421, and on the inner surface of the mounting part 100.

Meanwhile, it would be appreciated that an interval between the inner surface of the air guide member 211, 311, 411 or 421 and the outer surface of the blade 710 is always uniform (not shown).

A radiation increasing part having a predetermined area to increase radiation efficiency may protrude from the outer surface of the air guide member 211, 311, 411 or 421.

The concentratively discharging means 500 may be formed integrally with the air discharging means 200, 300 or 400.

Meanwhile, the concentratively discharging means 500 may include: a fitting part 510 detachably mounted on the air discharge slit 210; and a connecting part 520 for integrating the outer surface of the fitting part 510, and detachably mounted on the air discharging means 200, 300 or 400.

Motor mounting means 600, which has a motor 650, is installed on the lowermost air discharge guide member of the air discharge guide members 211, 311, 411 or 421 for rotating the cooling fan 700.

Here, it would be appreciated that the lowermost air discharge guide member and the motor mounting means 600 may be formed integrally with each other.

Also, it would be appreciated that the lowermost air discharge guide member and the motor mounting means 600 are separably coupled with each other.

The motor 650 may be located on the outer surface of the motor mounting means 600 as shown in FIG. 3, or may be located on the inner surface of the motor mounting means 600 as shown in FIG. 5.

As shown in FIGS. 6 and 9, the motor mounting means 600 may be in the form of a plate.

As shown in FIGS. 7 and 10, the motor mounting means 600 includes: a ring type coupling member 610 coupled with the lowermost air discharge guide member; a motor mounting part 620, which is arranged on the inner surface of the coupling member 610, and on which the motor is mounted; and a bridge part 620 for connecting the motor mounting part 620 and the coupling member 610 with each other.

Here, as the heating element, a CPU (Central Processing Unit) is used.

In the above, the structure of the radiation element was described.

Hereinafter, a heating element cooling device using the radiation element will be described.

The heating element cooling device according to the present invention includes a sirocco fan 700 on which a number of blades 710 are mounted in the circumferential direction, a radiation element, a motor 650, and a motor mounting means 600.

The radiation element includes: a mounting part 100 for attaching a heating element 800; and air discharging means 200, 300 or 400 mounted on the mounting part 100 and having a space for receiving the sirocco fan 700 and a number of air discharge slits 210 for discharging the air in the perpendicular direction to the blades along the circumference of the sirocco fan 700.

The motor 650 rotates the sirocco fan 700 contained in the radiation element.

The motor mounting means 600 is to mount the motor 650 on a side of the radiation element.

The heating element cooling device according to the present invention has at least one or more concentratively discharging means 500 mounted inside the air discharge slit 210 for branching and discharging the air generated from the sirocco fan 700 and for concentratively discharging the air to a specific area by blocking a predetermined section of the air discharge slit 210.

It is preferable that the concentratively discharging means 500 are mounted in the same direction as the blades 710 in a straight line.

The air discharging means 200, 300 or 400, the concentratively discharging means 500 and the heating element 800 will not be described as they have the same structure as the radiation element.

Meanwhile, as shown in FIGS. 12 and 13, the heating element cooling device includes: a sirocco fan 700 having a number of blades 710 mounted in the circumferential direction thereof; a radiation element having a space for receiving the sirocco fan 700 and air discharging means 50, which has a number of air discharge slit 210 formed by a number of air discharge guide members 211 mounted at regular intervals in the same direction as the blades 710 along the circumference of the sirocco fan 700; a motor 650 for rotating the sirocco fan 700 contained in the radiation element; and mounting means 600 for mounting the motor 650 and the heating element 800.

Here, the reference numeral 651 designates a motor shaft, 654 designates a connection bracket formed on the motor, 655 designates a bolt for connecting the connection bracket and the mounting means 600, and 652 designates a connection member forcedly inserted into a mounting part 653 formed on the sirocco fan 700 for connecting the motor shaft 651.

As shown in the following table 1 obtained by testing the prior art and the present invention, the present invention reduces noise by remarkably reducing an amount of wind of the sirocco fan collided against the outer wall of the radiation element, and increases discharge air volume by reducing the amount of wind collided against the air discharge guide members, thereby rapidly discharging heat transferred from the heating element through the radiation element via the wind.

TABLE 1

| | Noise (dB) | Temperature (° C.) |
|---|---|---|
| Prior art | 40.8 | 59.2 |
| The present | 35.3 | 54.9 |
| invention | | |

### INDUSTRIAL APPLICABILITY

As described above, according to the present invention, the radiation element and the cooling device using the radiation element can reduce noise, increase discharge air volume, and improve cooling efficiency.

While the present invention has been described with reference to the particular illustrative embodiments, it is not to be restricted by the embodiments but only by the appended claims. It is to be appreciated that those skilled in the art can change or modify the embodiments without departing from the scope and spirit of the present invention

1. A radiation element comprising:
a mounting part (100) on which a heating element is mounted;
air discharging means (200)(300)(400) mounted on the mounting part (100) having a space for receiving a cooling fan and a number of air discharge slits (210) for discharging air generated from the cooling fan in the horizontal direction along the circumference of the cooling fan.

2. The radiation element according to claim 1, further comprising at least one or more concentratively discharging means (500) mounted inside the air discharge slit (210) for branching and discharging the air generated from the cooling fan and for concentratively discharging the air to a specific area by blocking a predetermined section of the air discharge slit (210).

3. The radiation element according to claim 2, wherein the concentratively discharging means (500) are mounted in a straight line.

4. The radiation element according to claim 2, wherein the air discharging means (200) includes a number of air discharge guide members (211) separated from each other and piled up on another to form the air discharge slit (210).

5. The radiation element according to claim 4, wherein the air discharge guide members (211) of the air discharging means (200) and the mounting part (100) are integrated with each other into one.

6. The radiation element according to claim 2, wherein the air discharging means (300) includes:
a number of unit members (310) piled up on another, the unit member (310) having a ring type air discharge guide member, which has a receiving hole (311a) for receiving the cooling fan, and a mounting member (110) protruding from a side of the air discharge guide member (311) for mounting the heating element;
spacers (320) located between the mounting members (110) of the unit members (310) for forming the air discharge slit (210) between the air discharge guide members (311); and
coupling means (330) for connecting and fixing the spacer (320) and the mounting member (110) with each other,
wherein the mounting part (100) is formed by the mounting members (110) piled up on another and the air discharging means (300) is formed by the air discharge guide members (311).

7. The radiation element according to claim 2, wherein the air discharging means (300) includes:
a first unit member (410) having a first mounting member (110) for mounting the heating element, and an air discharge guide member (411) protruding integrally from a side of the mounting member (110) and having a receiving hole (411a) for receiving half of the cooling fan;
a second unit member (420) having a second mounting member (110) put on the upper surface of the first mounting member (110) of the first unit member (410) for mounting the heating element, and an air discharge guide member (421) protruding integrally from a side of the second mounting member (110) opposed to the air discharge guide member (411) of the first unit member (410), the air discharge guide member (421) having a receiving hole (421a) for receiving the other half of the cooling fan, the end portion of the air discharge guide member (421) is put on the air discharge guide member (411) of the first unit member (410) to form the air discharge slit (210); and
coupling means (430) for connecting and fixing the air discharge guide members (411)(421) and the mounting members (110) of the first and second unit members (410)(420) piled up on another in order,
wherein the mounting part (100) is formed by a number of the mounting members (110) piled up on another.

8. (canceled)

9. The radiation element according to claim 5, wherein if a number of the concentratively discharging means (500) are mounted, the interval between the inner surface of the air discharge guide member (211)(311)(411)(421) and the outer surface of the blade (710) of the cooling fan (700) is gradually increased from the mounting part (100) to the front end of the concentratively discharging means (500), gradually increased from the rear end of the concentratively discharging means (500) to the front end of another concentratively discharging means (500), and gradually increased from rear end of the latter concentratively discharging means (500) to the mounting part (100).

10. The radiation element according to claim 5, wherein the interval between the inner surface of the air guide member (211)(311)(411)(421) and the outer surface of the blade (710) is always uniform.

11. The radiation element according to claims 5, wherein a radiation increasing part having a predetermined area to increase radiation efficiency protrudes from the outer surface of the air guide member (211)(311)(411)(421).

12.-20. (canceled)

21. The radiation element according to claim 1, wherein the heating element is a CPU (Central Processing Unit).

22. A device for cooling a heating element comprising:
a sirocco fan (700) having a number of blades (710) mounted in the circumferential direction thereof;
a radiation element having a space for receiving the sirocco fan (700) and air discharging means (500), which has a number of air discharge slits(210) formed by a number of air discharge guide members (211) mounted at regular intervals in the same direction as the blades (710) along the circumference of the sirocco fan (700);
a motor (650) for rotating the sirocco fan (700) contained in the radiation element; and
mounting means (600) for mounting the motor (650) and a heating element (800).

23.-36. (canceled)

37. The radiation element according to claim 6, wherein if a number of the concentratively discharging means (500) are mounted, the interval between the inner surface of the air discharge guide member (211)(311)(411)(421) and the outer surface of the blade (710) of the cooling fan (700) is gradually increased from the mounting part (100) to the front end of the concentratively discharging means (500), gradually increased from the rear end of the concentratively discharging means (500) to the front end of another concentratively discharging means (500), and gradually increased from rear end of the latter concentratively discharging means (500) to the mounting part (100).

38. The radiation element according to claim 7, wherein if a number of the concentratively discharging means (500) are mounted, the interval between the inner surface of the air discharge guide member (211)(311)(411)(421) and the outer surface of the blade (710) of the cooling fan (700) is gradually increased from the mounting part (100) to the front end of the concentratively discharging means (500), gradually increased from the rear end of the concentratively discharging means (500) to the front end of another concentratively discharging means (500), and gradually increased from rear end of the latter concentratively discharging means (500) to the mounting part (100).

39. The radiation element according to claim 6, wherein the interval between the inner surface of the air guide member (211)(311)(411)(421) and the outer surface of the blade (710) is always uniform.

40. The radiation element according to claim 7, wherein the interval between the inner surface of the air guide member (211)(311)(411)(421) and the outer surface of the blade (710) is always uniform.

41. The radiation element according to claim 6, wherein a radiation increasing part having a predetermined area to increase radiation efficiency protrudes from the outer surface of the air guide member (211)(311)(411)(421).

42. The radiation element according to claim 7, wherein a radiation increasing part having a predetermined area to increase radiation efficiency protrudes from the outer surface of the air guide member (211)(311)(411)(421).
